(19) United States
(12) Patent Application Publication
(10) Pub. No.: US 2012/0249944 A1
(43) Pub. Date: Oct. 4, 2012

(54) ELECTROOPTIC DEVICE SUBSTRATE, ELECTROOPTIC DEVICE, METHOD OF MANUFACTURING ELECTROOPTIC DEVICE, AND ELECTRONIC APPARATUS

(75) Inventor: Masahito Yoshii, Chitose-shi (JP)

(73) Assignee: Seiko Epson Corporation, Tokyo (JP)

(21) Appl. No.: 13/425,615

(22) Filed: Mar. 21, 2012

(30) Foreign Application Priority Data
Mar. 29, 2011 (JP) 2011-071842

(51) Int. Cl. G02F 1/1345; H05K 13/00

(52) U.S. Cl. 349/152; 29/825

(57) ABSTRACT

In at least one embodiment of the disclosure, an electrooptic device substrate includes a plurality of electrooptic devices. A first electrooptic device includes a first wiring which electrically connects a first terminal and a first circuit. A second wiring electrically connects a second terminal and a second circuit. A first static electricity protection circuit is electrically connected to the first wiring. A second static electricity protection circuit is electrically connected to the second wiring. A short-circuit wiring is electrically connected to the first terminal and the second terminal. The short-circuit wiring is arranged so as to extend from the first electrooptic device and over a second electrooptic device from the plurality of electrooptic devices which is adjacent to the first electrooptic device.

### CROSS-REFERENCE

The present application claims priority from Japanese Patent Application No. 2011-071842 filed on Mar. 29, 2011 which is hereby incorporated by reference in its entirety.

### BACKGROUND

In certain electrooptic devices, there are active matrix driving-type liquid crystal devices including transistors as elements for switch-controlling pixel electrodes. A transistor is provided for each pixel. As a method of manufacturing the liquid crystal device, an element-side mother substrate and a counter-side mother substrate are bonded to each other through a liquid crystal layer. A plurality of element substrates on which pixel circuits including the above transistors are formed are imposed on the element-side mother substrate. A plurality of counter substrates which are arranged so as to be opposed to the element substrates are imposed on the counter-side mother substrate in the same manner. Thereafter, the above pair of mother substrates are divided so as to obtain each liquid crystal devices.

However, static electricity is generated when wirings, contact holes, and the like are formed in a process of manufacturing the above liquid crystal device. In some cases, the above transistors are electrostatically broken due to static electricity. In order to solve this problem, a method of protecting the above transistors from static electricity by providing a short ring has been disclosed in JP-A-7-244292.

However, this method is not sufficient. There is needed a function of a static electricity protection circuit of a power supply system including peripheral circuits to be enhanced in the manufacturing process.

### SUMMARY

In an electrooptic device substrate according to an embodiment, one electrooptic device of a plurality of electrooptic devices includes a data line driving circuit, a scan line driving circuit, a first constant potential wiring which electrically connects a first terminal and the data line driving circuit and to which a predetermined potential is supplied, a second constant potential wiring which electrically connects a second terminal and the scan line driving circuit and to which the predetermined potential is supplied, a first static electricity protection circuit which is electrically connected to the first constant potential wiring, a second static electricity protection circuit which is electrically connected to the second constant potential wiring and a short-circuit wiring which is arranged and stretched over between the one electrooptic device and an electrooptic device which is adjacent to the one electrooptic device and electrically connects the first terminal and the second terminal.

With this configuration, the first terminal and the second terminal to which the same predetermined potential is supplied are electrically connected to each other with the short-circuit wiring. With this, a function as a static electricity protection circuit can be enhanced in comparison with a case in which a short ring is provided on one driving circuit. To be more specific, static electricity can be dispersed by the short-circuit wiring which connects the first terminal and the second terminal. This makes it possible to prevent the static electricity from being locally charged. Therefore, the static electricity generated in a manufacturing process can be prevented from being concentrated on a local part. Accordingly, the function of the static electricity protection circuit on the data line driving circuit and the scan line driving circuit can be enhanced. For example, transistors, semiconductor elements, and diodes included in the data line driving circuit and the scan line driving circuit can be prevented from being broken due to the static electricity. In addition, wirings at the same predetermined potential are increased so that variation of the potential with respect to an amount of electric charge can be made smaller and the function of the static electricity protection circuit can be enhanced. It is to be noted that the constant potential wiring is a wiring to which a constant potential is applied and includes a wiring (Vss) to which a reference voltage is applied and a wiring such as a GND wiring to which a different potential is applied.

In the electrooptic device substrate according to another embodiment of the disclosure, the one electrooptic device has a plurality of wiring layers, and the short-circuit wiring is connected to a wiring layer which is the closest to the substrate among the plurality of wiring layers.

With this configuration, the short-circuit wiring is connected to the wiring layer which is closer to the substrate. That is to say, the short-circuit wiring is formed at an early stage in the manufacturing process so that wirings, circuits, and the like, which are to be formed thereafter, can be protected from the static electricity.

In the electrooptic device substrate according to another embodiment of the disclosure, the one electrooptic device includes a third constant potential wiring which electrically connects a third terminal and the data line driving circuit and to which a second predetermined potential which is different from the predetermined potential is supplied. A fourth constant potential wiring electrically connects a fourth terminal and the scan line driving circuit and to which the second predetermined potential is supplied. A third static electricity protection circuit is electrically connected to the third constant potential wiring, a fourth static electricity protection circuit is electrically connected to the fourth constant potential wiring, and a second short-circuit wiring is arranged and stretched over between the one electrooptic device and an electrooptic device which is adjacent to the one electrooptic device and electrically connects the third terminal and the fourth terminal.

With this configuration, the static electricity protection circuits are connected to the data line driving circuit and the scan line driving circuit. Further, the short-circuit wiring is formed so that the function of the static electricity protection circuit can be enhanced. Therefore, transistors included in the data line driving circuit and the scan line driving circuit can be protected from the static electricity.

An electrooptic device according to another embodiment of the disclosure is formed by using the above electrooptic device substrate.

With this configuration, since constant potential wirings at the same potential are connected to each other with the short-circuit wiring, the potential can be fixed. Therefore, the static electricity can be dispersed with the wirings at the same potential. Therefore, charges can be prevented from being concentrated on a local part of the wirings so that the transistors and the like can be prevented from being broken due to static electricity.

A method of manufacturing an electrooptic device from an electrooptic device substrate on which a plurality of electrooptic devices are formed according to another embodiment of the disclosure includes forming, on a substrate corresponding to one electrooptic device of the plurality of electrooptic devices, a data line driving circuit, a scan line driving circuit, a first constant potential wiring which electrically connects a first terminal and the data line driving circuit and to which a predetermined potential is supplied, a second constant potential wiring which electrically connects a second terminal and the scan line driving circuit and to which the predetermined potential is supplied, a first static electricity protection circuit which is electrically connected to the first constant potential wiring, a second static electricity protection circuit which is electrically connected to the second constant potential wiring, and a short-circuit wiring which is arranged and stretched over between the one electrooptic device and an electrooptic device which is adjacent to the one electrooptic device and electrically connects the first terminal and the second terminal; and cutting the short-circuit wiring.

As such, the first terminal and the second terminal to which the same predetermined potential is supplied are electrically connected to each other with the short-circuit wiring, thereby enhancing a function as a static electricity protection circuit. Specifically, static electricity can be dispersed by the short-circuit wiring which connects the first terminal and the second terminal. This makes it possible to prevent the static electricity from being locally charged. Therefore, the static electricity generated in a manufacturing process can be prevented from being concentrated on a local part. Accordingly, the function of the static electricity protection circuit on peripheral circuits including the data line driving circuit and the scan line driving circuit can be enhanced. For example, transistors, semiconductor elements, and diodes included in the data line driving circuit and the scan line driving circuit can be prevented from being broken due to the static electricity. In addition, wirings at the same potential are increased so that variation of the potential with respect to an amount of electric charge can be made smaller and the function of the static electricity protection circuit can be enhanced.

An electronic apparatus according to another embodiment of the disclosure includes the above electrooptic device.

With this configuration, the electronic apparatus includes the electrooptic device in which preventive measures against the static electricity in a manufacturing process are reinforced and which can be manufactured with excellent yield. Therefore, an electronic apparatus having high cost performance can be provided.

### BRIEF DESCRIPTION OF THE DRAWINGS

Non-limiting and non-exhaustive embodiments of the present disclosure will be described with reference to the accompanying drawings, wherein like numbers reference like elements.

FIG. 1 is a schematic plan view illustrating a configuration of a mother substrate.

FIG. 2 is an enlarged plan view illustrating a part II of the mother substrate of FIG. 1 in an enlarged manner.

FIG. 3 is a schematic plan view illustrating a configuration of a liquid crystal device.

FIG. 4 is a schematic cross-sectional view cut along a line IV-IV of the liquid crystal device as illustrated in FIG. 3.

FIG. 5 is an equivalent circuit diagram illustrating an electric configuration of the liquid crystal device.

FIG. 6 is a schematic cross-sectional view illustrating a configuration of the liquid crystal device.

FIG. 7 is a schematic plan view illustrating a part VII of the mother substrate as illustrated in FIG. 2 in an enlarged manner.

FIG. 8 is an equivalent circuit diagram illustrating an example of a static electricity protection circuit.

FIG. 9 is a flowchart illustrating a method of manufacturing a liquid crystal device.

FIGS. 10A to 10C are schematic plan views illustrating a part of the process in the method of manufacturing a liquid crystal device.

FIG. 11 is a plan view schematically illustrating a configuration of a liquid crystal projector as one example of an electronic apparatus including the liquid crystal device.

### DESCRIPTION OF EXEMPLARY EMBODIMENTS

Hereinafter, embodiments of the disclosure will be described with reference to the accompanying drawings. It is to be understood, however, that other embodiments may be utilized and changes may be made without departing from the scope of the present disclosure. Therefore, the following detailed description is not to be taken in a limiting sense, and the scope of the present disclosure is defined by the appended claims and their equivalents. Also, it is to be noted that the drawings used for description are illustrated in an enlarged or contracted manner, as appropriate, such that a part to be described can be well recognized.

### Configuration of Mother Substrate

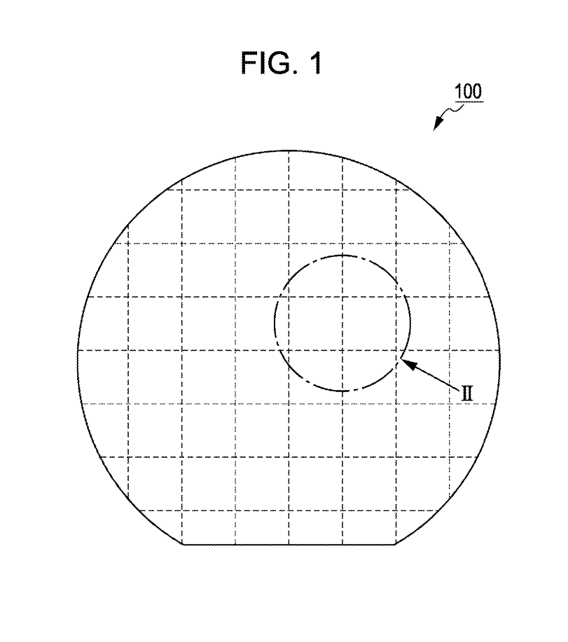

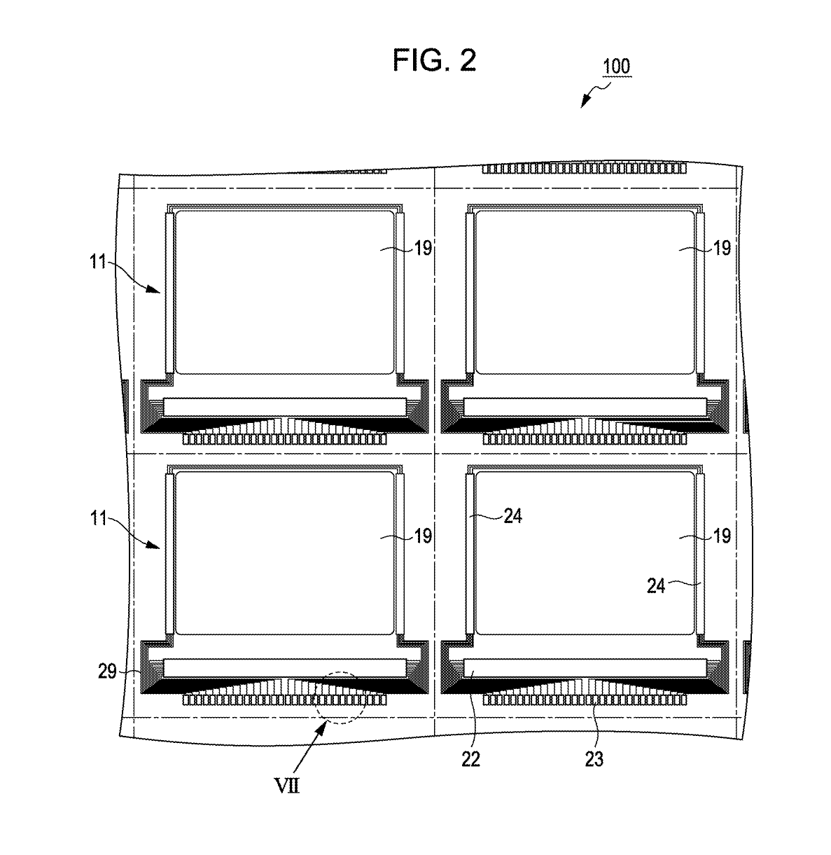

FIG. 1 is a schematic plan view illustrating a configuration of a mother substrate as an electrooptic device substrate. FIG. 2 is an enlarged plan view illustrating a part II of the mother substrate as illustrated in FIG. 1 in an enlarged manner. Hereinafter, the configuration of the mother substrate is described with reference to FIG. 1 and FIG. 2.

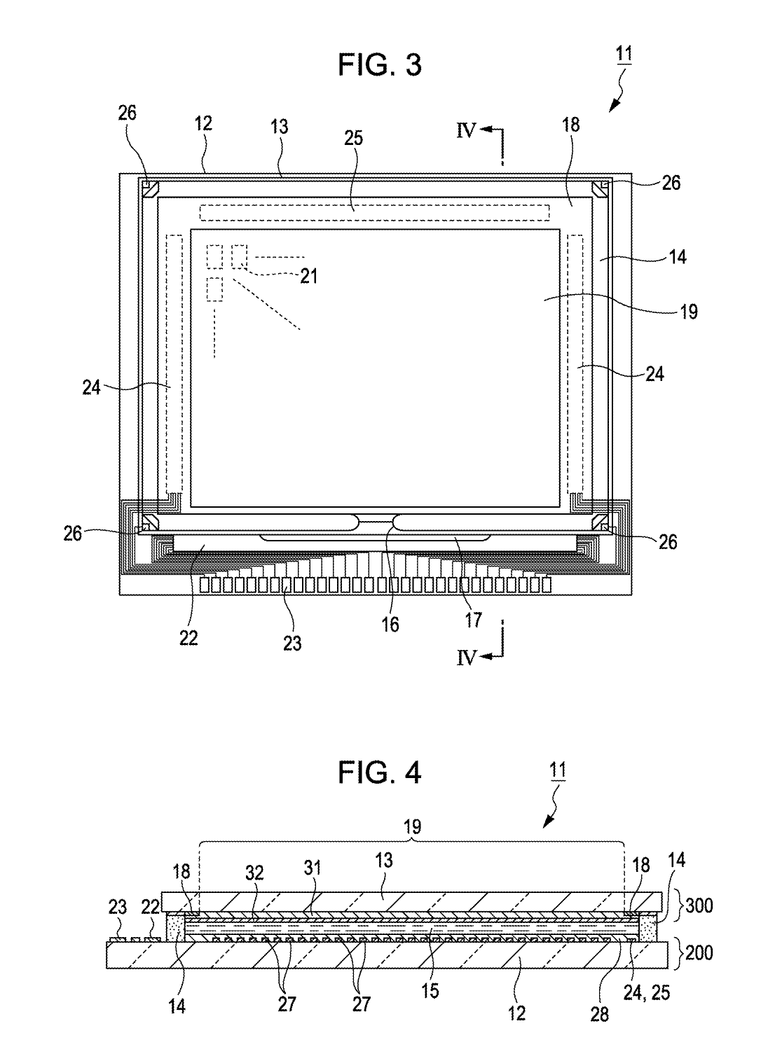

As illustrated in FIG. 1, a mother substrate 100 is used when a liquid crystal device 11 (see, FIG. 3) is manufactured, for example. A plurality of substrates (for example, element substrate) each of which is one of a pair of substrates constituting the liquid crystal device 11 are imposed on the mother substrate 100 in a matrix form. A size of the mother substrate 100 is 8 inches, for example. A thickness of the mother substrate 100 is 1.2 mm, for example. A material of the mother substrate 100 is quartz, for example.

It is to be noted that a shape of the mother substrate 100 is not limited to a circular shape when seen from the above and may be a shape having an orientation flat on which a part of a circumference is cut out.

As illustrated in FIG. 2, a data line driving circuit 22, scan line driving circuits 24, and external connection terminals 23 as peripheral circuits are formed on the periphery of a display region 19 on each liquid crystal device 11. The data line driving circuit 22, the scan line driving circuits 24 and the external connection terminals 23 are electrically connected to each other with a signal wiring 29. Hereinafter, a configuration of the liquid crystal device 11 which is finally formed by performing a processing on the mother substrate 100 is described.

### Configuration of Electrooptic Device

FIG. 3 is a schematic plan view illustrating a configuration of the liquid crystal device as an electrooptic device. FIG. 4 is a schematic cross-sectional view cut along a line IV-IV of the liquid crystal device as illustrated in FIG. 3. Hereinafter, the configuration of the liquid crystal device is described with reference to FIG. 3 and FIG. 4.

As illustrated in FIG. 3 and FIG. 4, the liquid crystal device 11 is a TFT active matrix-type liquid crystal device using thin film transistors (hereinafter, referred to as “Thin Film Transistor (TFT) element”) as switching elements for pixels, for example. The liquid crystal device 11 is formed by bonding an element substrate 200 and a counter substrate 300 through a sealing member 14 having a substantially rectangular frame shape when seen from the above. The element substrate 200 and the counter substrate 300 constitute a pair of substrates.

A first substrate 12 constituting the element substrate 200 and a second substrate 13 constituting the counter substrate 300 are formed by a translucent material such as glass or quartz, for example. The liquid crystal device 11 has a configuration in which a liquid crystal layer 15 is sealed within a region surrounded by the sealing member 14. It is to be noted that an inlet 16 through which liquid crystal is injected is provided on the sealing member 14 and the inlet 16 is sealed by a sealing member 17.

For example, a liquid crystal material having positive dielectric constant anisotropy is used for the liquid crystal layer 15. In the liquid crystal device 11, a frame light shielding film 18 having a rectangular frame shape when seen from the above is formed on the second substrate 13 along the vicinity of an inner circumference of the sealing member 14 and an inner region of the frame light shielding film 18 corresponds to a display region 19. The frame light shielding film 18 is made of a light shielding material.

The frame light shielding film 18 is formed with aluminum (Al) as a light shielding material, for example, and is provided so as to define an outer circumference of the display region 19 at the side of the second substrate 13.

Pixel regions 21 are provided in the display region 19 in a matrix form. Each pixel region 21 constitutes one pixel as a minimum display unit of the display region 19. The data line driving circuit 22 and the external connection terminals 23 are formed on an outer region of the sealing member 14 along one side of the first substrate 12 (lower side in FIG. 3).

Further, the scan line driving circuits 24 are formed on an inner region of the sealing member 14 along two sides which is adjacent to the above one side. A test circuit 25 is formed along the remaining one side of the first substrate 12 (upper side in FIG. 1). The frame light shielding film 18 formed at the side of the second substrate 13 is formed at a position opposed to the scan line driving circuits 24 and the test circuit 25 which are formed on the first substrate 12, for example. In other words, the frame light shielding film 18 is formed at a position overlapping with the scan line driving circuits 24 and the test circuit 25 when seen from the above.

On the other hand, vertical conducting terminals 26 are arranged on corner portions (for example, four corner portions of the sealing member 14) of the counter substrate 300. The vertical conducting terminals 26 electrically conduct between the element substrate 200 and the counter substrate 300.

Further, as illustrated in FIG. 4, a plurality of pixel electrodes 27 are formed on the first substrate 12 at the side of the liquid crystal layer 15. A first alignment film 28 is formed so as to cover these pixel electrodes 27. The pixel electrodes 27 are conductive films made of a transparent conductive material such as Indium Tin Oxide (ITO).

On the other hand, a grid-form light shielding film (blak matrix (BM)) (not illustrated) is formed on the second substrate 13 at the side of the liquid crystal layer 15 and a common electrode 31 is formed on the light shielding film. The common electrode 31 is formed in a solid form when seen from the above. Further, a second alignment film 32 is formed on the common electrode 31. The common electrode 31 is a conductive film made of a transparent conductive material such as ITO.

The liquid crystal device 11 is a transmissive type and a polarizing plate (not illustrated) and the like are arranged on each of the element substrate 200 and the counter substrate 300 at a light incident side and a light exiting side. It is to be noted that a configuration of the liquid crystal device 11 is not limited thereto and the liquid crystal device 11 may be configured to be a reflection type or a semi-transmissive type.

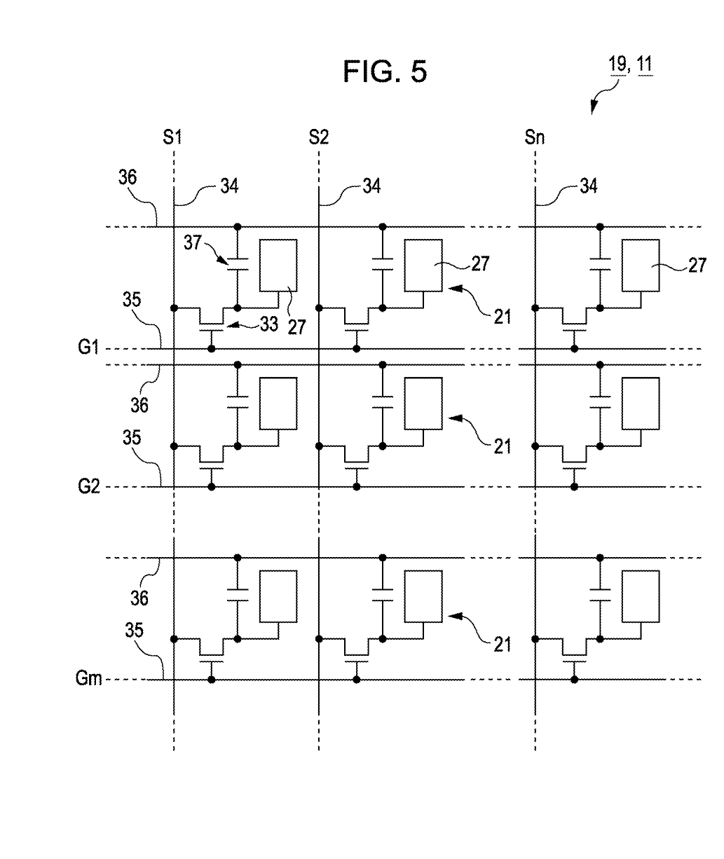

FIG. 5 is an equivalent circuit diagram illustrating an electric configuration of the liquid crystal device. Hereinafter, the electric configuration of the liquid crystal device is described with reference to FIG. 5.

As illustrated in FIG. 5, the liquid crystal device 11 has a plurality of pixel regions 21 constituting the display region 19. Each pixel electrode 27 is arranged on each pixel region 21. Further, a TFT element 33 is formed on each pixel region 21.

Each TFT element 33 is a switching element which performs conduction control on each pixel electrode 27. Data lines 34 are electrically connected to sources of the TFT elements 33. Image signals S1, S2, . . . , Sn are supplied to the data lines 34 from the data line driving circuit 22 (see, FIG. 3), for example.

Further, gate electrodes 35 of the TFT elements 33 are electrically connected to a scan line 41. Scan signals G1, G2, . . . , Gm are supplied to the scan line 41 from the scan line driving circuits 24 (see, FIG. 3), for example, at a predetermined timing in a pulse manner. Further, the pixel electrodes 27 are electrically connected to drains of the TFT elements 33.

The TFT elements 33 as the switching elements are made to in an ON state only for a constant period of time with the scan signals G1, G2, . . . , Gm supplied from the scan line 41. With this, the image signals S1, S2, . . . , Sn supplied from the data lines 34 are written into the pixel regions 21 through the pixel electrodes 27 at a predetermined timing.

The image signals S1, S2, . . . , Sn at a predetermined level, which have been written into the pixel regions 21, are held by liquid crystal capacitors formed between the pixel electrodes 27 and the common electrode 31 (see, FIG. 4) for a constant period of time. It is to be noted that storage capacitors 37 are formed between the pixel electrodes 27 and capacitor lines 36 in order to prevent the held image signals S1, S2, . . . , Sn from being leaked.

If a voltage signal is applied to the liquid crystal layer 15 in this manner, an alignment state of liquid crystal molecules changes depending on an applied voltage level. With this, light incident onto the liquid crystal layer 15 is modulated so that image light is generated.

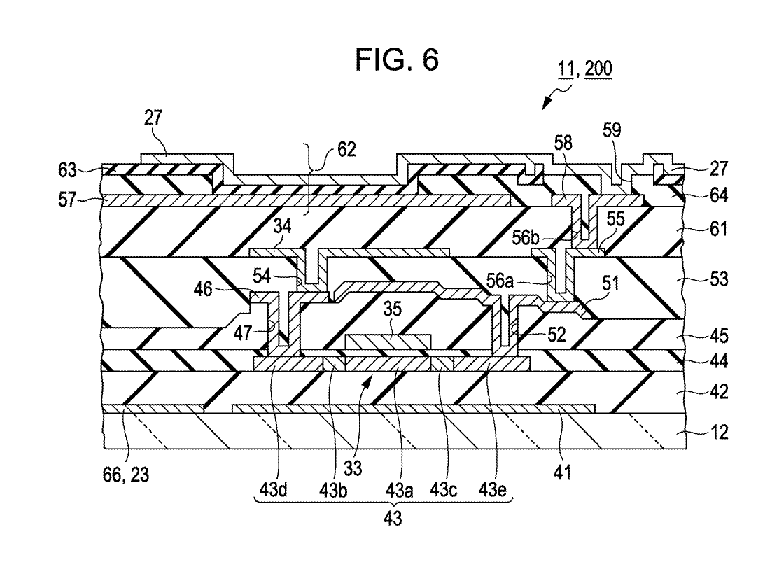

FIG. 6 is a schematic cross-sectional view illustrating a configuration of the liquid crystal device. Hereinafter, the configuration of the liquid crystal device is described with reference to FIG. 6. It is to be noted that FIG. 6 illustrates a cross-sectional positional relationship among constituent components and scales of the constituent components are set such that they are clearly illustrated. Further, FIG. 6 illustrates only the element substrate of the element substrate and the counter substrate, which constitute the liquid crystal device.

As illustrated in FIG. 6, the liquid crystal device 11 has the element substrate 200 and the counter substrate 300 (not illustrated). The scan line (lower light shielding film) 41 made of titanium (Ti), chromium (Cr), or the like is formed on the first substrate 12 of the element substrate 200. As described above, the scan line 41 is electrically connected to the gate electrodes 35 through contact holes so as to function as a scan line. The scan line 41 is patterned into a stripe shape when seen from the above and defines a part of an opening region of each pixel region 21. An underlying insulating film 42 formed by a silicon dioxide film or the like is formed on the first substrate 12 and the scan line 41.

The TFT element 33, the gate electrode 35, and the like are formed on the underlying insulating film 42. The TFT element 33 has a Lightly Doped Drain (LDD) structure, for example. The TFT element 33 has a semiconductor layer 43 made of polysilicon or the like, a gate insulating film 44 formed on the semiconductor layer 43, and the gate electrode 35 formed on the gate insulating film 44 and formed by a polysilicon film or the like. As described above, the gate electrode 35 is electrically connected to the scan line 41. Further, a short-circuit wiring 66 is provided on the same layer as the scan line 41 to connect the external connection terminals 23 to each other, which will be described later.

The semiconductor layer 43 includes a channel region 43a, a lightly doped source region 43b, a lightly doped drain region 43c, a heavily doped source region 43d, and a heavily doped drain region 43e. A channel of the channel region 43a is formed by an electric field from the gate electrode 35. A first interlayer insulating film 45 formed by a silicon dioxide film or the like is formed on the gate insulating film 44.

The heavily doped source region 43d of the TFT element 33 is electrically connected to a relay layer 46 formed on the first interlayer insulating film 45 through a contact hole 47. On the other hand, the heavily doped drain region 43e thereof is electrically connected to a relay layer 51 which is formed on the same layer as the relay layer 46 through a contact hole 52.

The relay layer 46 is electrically connected to the data line 34 formed on a second interlayer insulating film 53 through a contact hole 54. On the other hand, the relay layer 51 is electrically connected to a relay layer 55 which is formed on the same layer as the data line 34 through a contact hole 56a.

The relay layer 55 is further electrically connected to a relay layer 58 which is provided on the same layer as a capacitor electrode 57, which will be described later, through the contact hole 56b. Further, the relay layer 58 is electrically connected to the pixel electrode 27 through a contact hole 59. That is to say, the heavily doped drain region 43e of the TFT element 33 and the pixel electrode 27 are electrically relay-connected through the relay layer 51, the relay layer 55, and the relay layer 58 in this order.

A storage capacitor 62 is formed at the upper layer side of the data line 34 and the relay layer 55 through a third interlayer insulating film 61. The storage capacitor 62 is electrically connected to the liquid crystal capacitor in parallel. With this, a voltage of the pixel electrode 27 can be held for a longer time than a time for which an image signal is actually applied by three-digit, for example. Therefore, a holding characteristic of the liquid crystal element is improved, thereby realizing the liquid crystal device 11 having a high contrast ratio.

The capacitor electrode 57 functions as one electrode of the storage capacitor 62 which is electrically connected to the liquid crystal capacitor in parallel and is kept at a fixed potential. The capacitor electrode 57 is formed by a transparent electrode such as ITO, for example. Therefore, even if the capacitor electrode 57 is formed so as to overlap the display region 19 including the opening region, light transmissivity on the opening region can be suppressed from being lowered.

A dielectric film 63 is formed on the capacitor electrode 57. The dielectric film 63 is formed in a solid form so as to cover the capacitor electrode 57. It is to be noted that the dielectric film 63 is formed by silicon nitride or the like, which is a transparent dielectric material. Therefore, even if the dielectric film 63 is widely formed on the display region 19 including the opening region, light transmissivity on the opening region can be suppressed from being lowered. It is to be noted that in one embodiment, a film thickness of the dielectric film 63 be made thinner for making a capacitance value of the storage capacitor 62 higher.

Further, a capacitor separation film 64 for separating the storage capacitor 62 between the pixels is formed on the capacitor electrode 57. The capacitance value of the storage capacitor 62 can be adjusted by increasing or decreasing an area of the capacitor separation film 64.

The pixel electrode 27 is formed on the capacitor separation film 64. The pixel electrode 27 is formed into an island form for each of pixels which are divided by the data lines 34 and the scan line 41 in a matrix form. It is to be noted that although not illustrated in FIG. 6, the first alignment film 28 (see, FIG. 4) for defining an alignment state of the liquid crystal molecules included in the liquid crystal layer 15 (see, FIG. 4) is formed on the pixel electrode 27.

The storage capacitor 62 is constituted by the capacitor electrode 57, the dielectric film 63 and the pixel electrode 27 each of which is transparent. Therefore, the opening region is not made smaller and an opening ratio which is a ratio of the opening region occupying each pixel is not made lower. In addition, with such storage capacitor 62, the storage capacitor 62 can be formed on the opening region. Therefore, the capacitance value thereof can be increased in comparison with a case where the storage capacitor is formed only on a non-opening region.

Although not illustrated in FIG. 6, a black matrix made of aluminum or the like is formed on the second substrate 13 of the counter substrate 300 at the side facing the liquid crystal layer 15. Further, a silicon dioxide film (SiO₂) is formed on the black matrix. Furthermore, the transparent common electrode (see, FIG. 4) is formed on the entire silicon dioxide film and the second alignment film 32 (see, FIG. 4) is formed so as to cover the common electrode 31 made of ITO or the like.

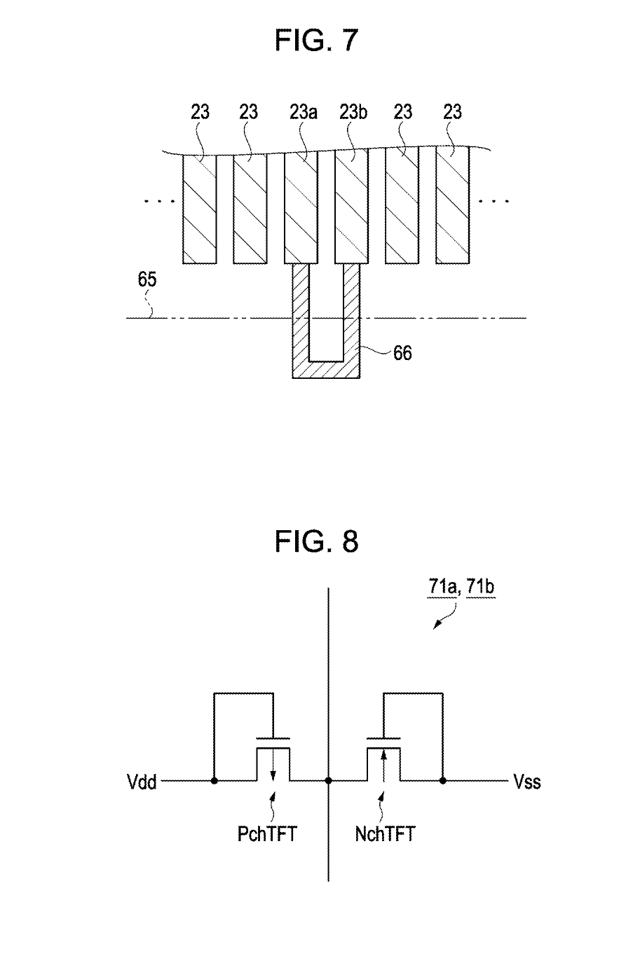

FIG. 7 is a schematic plan view illustrating a part VII (periphery of the external connection terminals) of the mother substrate as illustrated in FIG. 2 in an enlarged manner. FIG. 8 is an equivalent circuit diagram illustrating an example of a static electricity protection circuit. Hereinafter, a configuration of the periphery of the external connection terminals and a configuration of the static electricity protection circuit are described with reference to FIG. 7 and FIG. 8.

As illustrated in FIG. 7, the group of external connection terminals 23 has a plurality of external connection terminals 23 which are electrically connected to peripheral circuits (data line driving circuit 22, scan line driving circuits 24, and the like) provided on the periphery of the display region 19 with the signal wiring 29. A part of the signal wiring 29 is a power supply wiring to which a constant potential (predetermined potential) is applied. The power supply wiring is connected to Vssx and Vssy at a GND level and Vddx and Vddy at a potential of 15V, for example. Hereinafter, the Vssx and the Vssy at the GND level are described as an example.

The plurality of external connection terminals 23 have a first external connection terminal 23a (Vssx) as a first terminal and a second external connection terminal 23b (Vssy) as a second terminal. The first external connection terminal 23a is connected to a first constant potential wiring of the data line driving circuit 22, for example. Further, the second external connection terminal 23b is connected to second constant potential wirings of the scan line driving circuits 24, for example.

It is to be noted that the above Vddx is electrically connected to the data line driving circuit 22. Further, the Vddy is electrically connected to the scan line driving circuits 24.

A static electricity protection circuit 71a (first static electricity protection circuit) as illustrated in FIG. 8 is electrically connected to the first constant potential wiring which connects the first external connection terminal 23a and the data line driving circuit 22. A static electricity protection circuit 71b (second static electricity protection circuit) as illustrated in FIG. 8 is electrically connected to the second constant potential wiring which connects the second external connection terminal 23b and the scan line driving circuits 24 in the same manner.

The static electricity protection circuit 71a which is connected to the Vddx and the Vssx is provided for various signals (DX as a start pulse of a shift register, DIRX for controlling a shift direction of the shift register, and the like) to be supplied to the data line driving circuit 22. The static electricity protection circuit 71b which is connected to the Vddy and the Vssy is provided for various signals (DY, DIRY, and the like) to be supplied to the scan line driving circuits 24.

It is to be noted that the power supply wiring connected to the data line driving circuit 22 and the power supply wiring connected to the scan line driving circuits 24 are provided as the first external connection terminal 23a and the second external connection terminal 23b as two different terminals in a separated manner for the following reason. That is, the power supply wirings are provided in this manner such that operation noises of the data line driving circuit 22 and the scan line driving circuits 24 are not influenced by each other by separately supplying power supply voltages thereto from the outside even if the power supply voltages are at the same potential when the liquid crystal device 11 is operated.

Further, the first external connection terminal 23a and the second external connection terminal 23b which are at the same potential are electrically connected to each other at the outer side with respect to a scribe line 65 (between the electrooptic device and another electrooptic device). To be more specific, the first external connection terminal 23a and the second external connection terminal 23b are electrically connected to each other with the short-circuit wiring 66 used as a wiring for protecting them from static electricity.

To be more specific, the short-circuit wiring 66 continues over the outer side from the scribe line 65 used for cutting the mother substrate 100 into the plurality of liquid crystal devices 11. That is to say, the first external connection terminal 23a and the second external connection terminal 23b, which are connected to each other with the short-circuit wiring 66, are electrically disconnected from each other by dividing the mother substrate 100 into the plurality of liquid crystal devices 11. The short-circuit wiring 66 is a low-resistant wiring made of aluminum, polysilicon, or the like, for example.

In this manner, the first external connection terminal 23a and the second external connection terminal 23b to which the same potential is applied are electrically connected to each other with the short-circuit wiring 66 in a process of manufacturing the liquid crystal device 11 before the mother substrate 100 is divided. With this, a function of a static electricity protection circuit can be enhanced. That is to say, the static electricity protection circuit which is provided at the power supply wiring connected to the data line driving circuit 22 and the static electricity protection circuit which is provided at the power supply wiring connected to the scan line driving circuits 24 are combined, thereby functioning more effectively. Therefore, even if static electricity is generated when wirings, contact holes, and the like, are formed, the static electricity can be dispersed by the wirings at the same potential. This makes it possible to prevent the static electricity from being locally charged. Therefore, the static electricity can be prevented from being concentrated on a part of the wirings. Accordingly, the function of the static electricity protection circuit on the data line driving circuit 22 and the scan line driving circuits 24 can be enhanced.

For example, the TFT elements (transistors) included in the data line driving circuit 22 and the scan line driving circuits 24 can be prevented from being broken due to the static electricity. Further, wirings at the same potential are increased so that variation of the potential with respect to an amount of electric charge can be made smaller and the function of the static electricity protection circuit can be enhanced.

### Method of Manufacturing Electrooptic Device

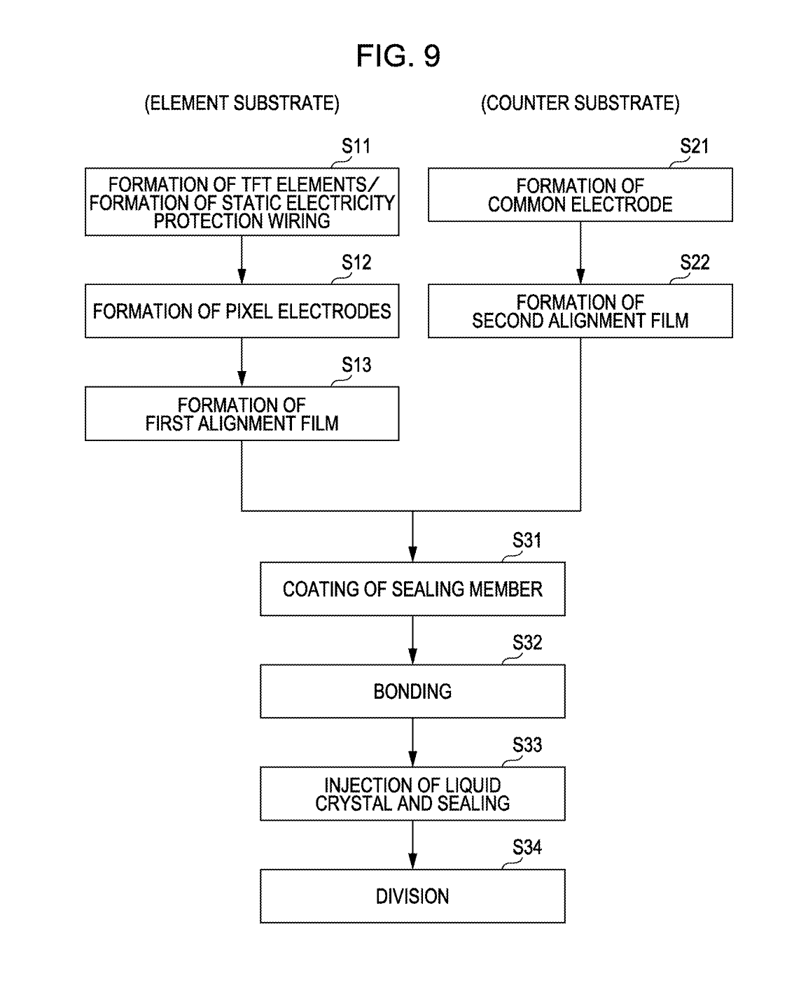

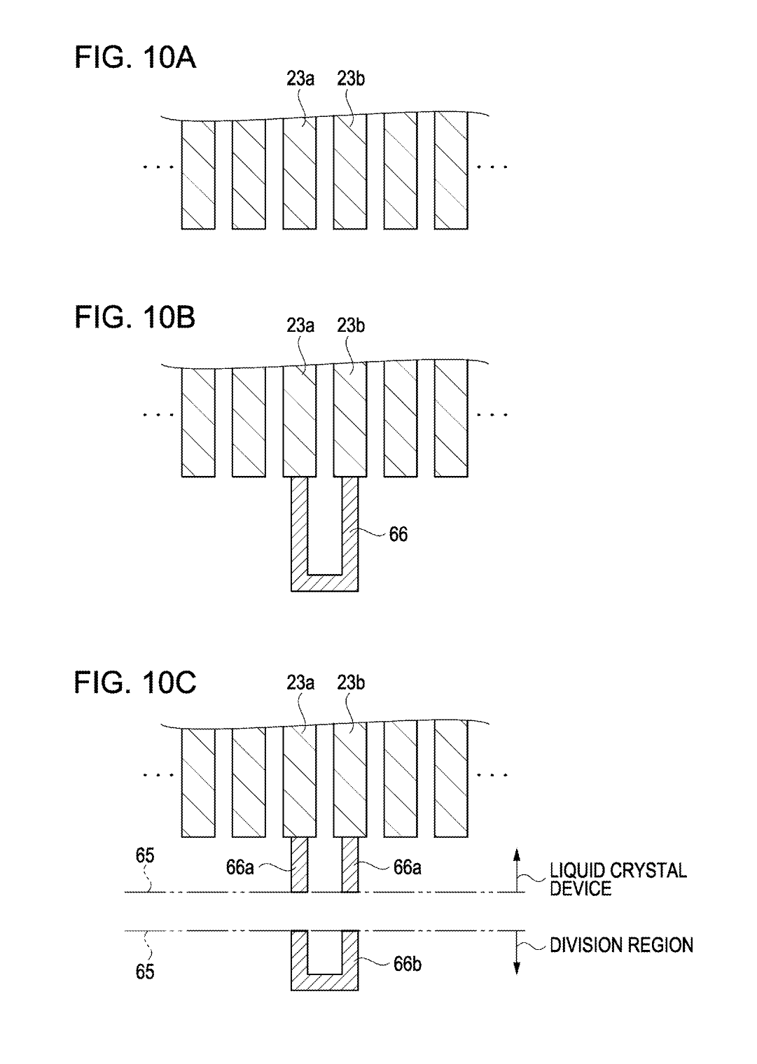

FIG. 9 is a flowchart illustrating a method of manufacturing the liquid crystal device as an electrooptic device in the order of processes. FIGS. 10A to 10C are schematic plan views illustrating a part of processes in the method of manufacturing the liquid crystal device. Hereinafer, the method of manufacturing the liquid crystal device is described with reference to FIG. 9 and FIGS. 10A to 10C.

At first, a method of manufacturing the element substrate 200 side is described. At step S11, the TFT elements 33 and the like are formed on the first substrate 12 formed by a quartz substrate or the like. To be more specific, the TFT elements 33 and the like are formed on the first substrate 12 using a well-known film formation technique, photolithography technique, and an etching technique.

Further, as illustrated in FIGS. 10A and 10B, the short-circuit wiring 66 is formed to electrically connect the first external connection terminal 23a and the second external connection terminal 23b at the same time as the above formation of the TFT elements 33 and the like. To be more specific, the short-circuit wiring 66 is formed on the same layer as the scan line 41, for example.

With this, the function of the static electricity protection circuit can be enhanced. Further, the TFT elements and the like included in the data line driving circuit 22 and the scan line driving circuits 24 as peripheral circuits can be suppressed from being electrostatically broken due to static electricity generated by forming the wirings, contact holes (see, FIG. 6), and the like thereafter.

Further, in certain embodiments the short-circuit wiring 66 is connected on a wiring layer which is closer to (and at least in one embodiment, a wiring layer which is the closest to) the first substrate 12. With this, since the short-circuit wiring 66 is formed at an early stage in the manufacturing process, the wirings, the contact holes, and the like, which are to be formed thereafter, can be protected from static electricity.

At step S12, the pixel electrodes 27 are formed. To be more specific, the pixel electrodes 27 are formed above the TFT elements 33 on the first substrate 12 using the well-known film formation technique, the photolithography technique, and the etching technique in the same manner as the formation of the TFT elements 33 and the like.

At step S13, the first alignment film 28 is formed above the pixel electrodes 27. As a method of manufacturing the first alignment film 28, an oblique evaporation method of obliquely evaporating an inorganic material such as silicon dioxide (SiO₂) is used, for example. With this, the element substrate 200 side is completed.

Next, a method of manufacturing the counter substrate 300 side is described. At first, at step S21, the common electrode 31 is formed on the second substrate 13 made of a translucent material such as a quartz substrate using the well-known film formation technique, the photolithography technique, and the etching technique.

At step S22, the second alignment film 32 is formed on the common electrode 31. The method of manufacturing the second alignment film 32 is the same as the method of manufacturing the first alignment film 28 and the oblique evaporation method is used, for example. With this, the counter substrate 300 side is completed. Next, a method of bonding the element substrate 200 and the counter substrate 300 to each other is described.

At step S31, the sealing member 14 is coated on the element substrate 200. To be more specific, the sealing member 14 is coated on a peripheral portion of the display region 19 on the element substrate 200 (so as to surround the display region 19) while changing a relative positional relationship between the element substrate 200 and a dispenser (discharge device is also available).

At step S32, the element substrate 200 and the counter substrate 300 are bonded to each other. To be more specific, the element substrate 200 and the counter substrate 300 are bonded to each other through the sealing member 14 coated on the element substrate 200. To be further more specific, the element substrate 200 and the counter substrate 300 are bonded to each other while ensuring positional accuracy of the substrates 12, 13 in the longitudinal direction and the lateral direction when seen from the above.

At step S33, liquid crystal is injected into the structure from the inlet 16 (see, FIG. 3). Thereafter, the inlet 16 is sealed. The sealing member 17 such as a resin is used for the sealing, for example.

At step S34, the mother substrate 100 is divided into the plurality of liquid crystal devices 11. To be more specific, as illustrated in FIG. 10C, the mother substrate 100 is divided along the scribe line 65. With this, the mother substrate 100 is cut out into the plurality of liquid crystal devices 11 and the short-circuit wiring 66 is divided into wirings 66a and a wiring 66b. Accordingly, the first external connection terminal 23a and the second external connection terminal 23b are electrically disconnected from each other. This makes it possible to suppress noise from shifting from one terminal to the other terminal, between the first external connection terminal 23a and the second external connection terminal 23b. With this, the liquid crystal device 11 is completed.

### Configuration of Electronic Apparatus

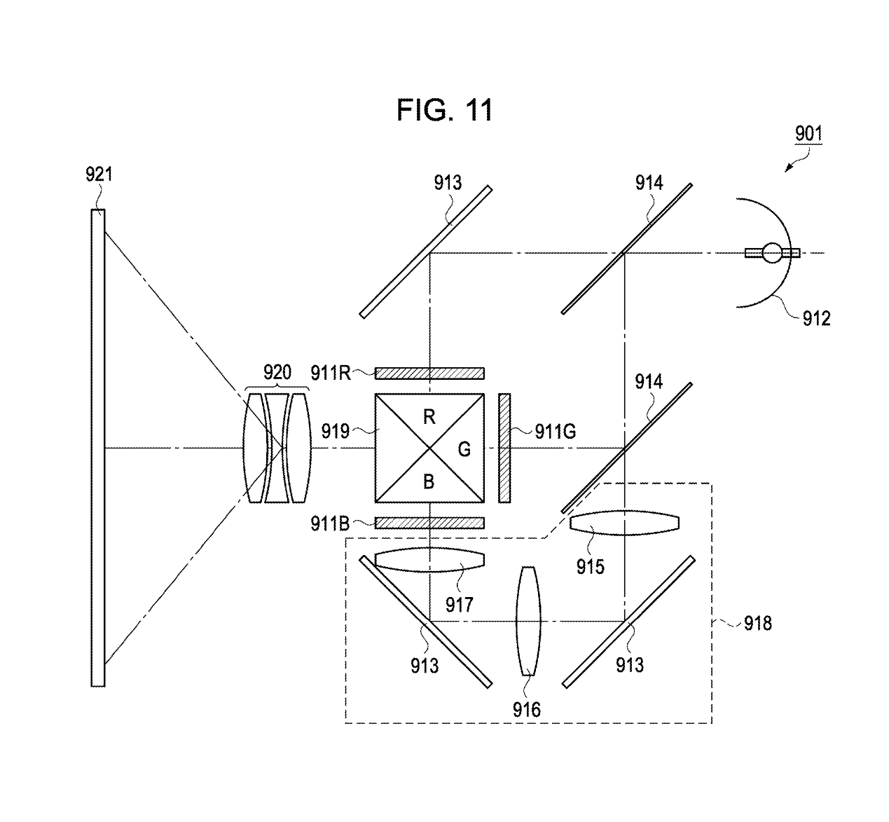

FIG. 11 is a plan view schematically illustrating a configuration of a liquid crystal projector as one example of an electronic apparatus including the above liquid crystal device. Hereinafter, the configuration of the liquid crystal projector including the liquid crystal device is described with reference to FIG. 11.

As illustrated in FIG. 11, a liquid crystal projector 901 has a configuration in which three liquid crystal modules are arranged to be used as light bulbs 911R, 911G, 911B for RGB. The above liquid crystal device 11 is applied to each of the three liquid crystal modules.

To be more specific, if projection light is emitted from a lamp unit 912 formed by a white light source such as a metal halide lamp, the projection light is separated into light components R, G, and B corresponding to three primary colors of RGB by three mirrors 913 and two dichroic mirrors 914. Then, the separated projection lights are guided to the light bulbs 911R, 911G, 911B corresponding to the colors. In particular, the light component B is guided to the light bulb 911B through a relay lens system 918 in order to prevent light loss on a long light path. The relay lens system 918 is constituted by an incident lens 915, a relay lens 916, and an exit lens 917.

The light components R, G, and B corresponding to three primary colors, which have been modulated by the light bulbs 911R, 911G, 911B, respectively, are combined by a dichroic prism 919 again. Thereafter, the combined light component is projected on a screen 921 through a projection lens 920 as a color image.

It is to be noted that the disclosure is not limited to the liquid crystal projector 901 on which three liquid crystal modules are arranged as described above. For example, the disclosure may be applied to a liquid crystal projector on which one liquid crystal module is arranged.

In the liquid crystal projector 901 having such configuration, the liquid crystal modules to which the above liquid crystal devices 11 are applied are used. Therefore, the the liquid crystal projector 901 can be efficiently assembled while suppressing cost of manufacturing the liquid crystal projector 901. It is to be noted that as an electronic apparatus including the liquid crystal device 11, various types of electronic apparatuses including a high-definition electric view finder (EVF), a mobile phone, a mobile computer, a digital camera, a digital video camera, a television, a display, a vehicle-mounted device, an audio device, an illumination device, and the like are exemplified in addition to the above liquid crystal projector 901.

As described in detail above, with the liquid crystal device 11, the method of manufacturing the liquid crystal device 11, and the electronic apparatus according to the embodiment, the following effects may be obtained.

1. With the liquid crystal device 11 according to the embodiment, power supply wirings (the first external connection terminal 23a and the second external connection terminal 23b) for the data line driving circuit 22 and the scan line driving circuits 24 are electrically connected to each other with the short-circuit wiring 66, thereby enhancing a function as a static electricity protection circuit. To be more specific, static electricity can be dispersed by the first external connection terminal 23a and the second external connection terminal 23b which are connected to each other. This makes it possible to prevent the static electricity from being locally charged. Therefore, the static electricity can be prevented from being concentrated on a part of the wirings. Accordingly, the function of the static electricity protection circuit on the data line driving circuit 22 and the scan line driving circuits 24 can be enhanced. For example, transistors, semiconductor elements, and diodes included in the data line driving circuit 22 and the scan line driving circuits 24 can be prevented from being broken due to the static electricity. In addition, power supply wirings at the same potential are increased so that variation of the potential with respect to an amount of electric charge can be made smaller and the function of the static electricity protection circuit can be enhanced.

2. With the liquid crystal device 11 according to the embodiment, the short-circuit wiring 66 is connected on a wiring layer (for example, same layer as the scan line 41) which is closer to the first substrate 12. That is to say, the short-circuit wiring 66 is formed at an early stage in the manufacturing process so that wirings, circuits, and the like, which are to be formed thereafter, can be protected from the static electricity.

3. With the method of manufacturing the liquid crystal device 11 according to the embodiment, power supply wirings (the signal wiring 29, the first external connection terminal 23a and the second external connection terminal 23b) are electrically connected to each other with the short-circuit wiring 66, thereby enhancing a function as a static electricity protection circuit. To be more specific, static electricity can be dispersed by the power supply wirings (signal wiring 29) which are connected to each other. This makes it possible to prevent the static electricity from being locally charged. Therefore, the static electricity can be prevented from being concentrated on a part of the wirings. Accordingly, the function of the static electricity protection circuit on the peripheral circuit including the data line driving circuit 22 and the scan line driving circuits 24 can be enhanced. For example, transistors, semiconductor elements, and diodes included in the data line driving circuit 22 and the scan line driving circuits 24 can be prevented from being broken due to the static electricity. In addition, wirings at the same potential, such as the power supply wirings, are increased so that variation of the potential with respect to an amount of electric charge can be made smaller and the function of the static electricity protection circuit can be enhanced.

4. With the electronic apparatus according to the embodiment, the electronic apparatus includes the liquid crystal device 11 in which a measure against the static electricity in a manufacturing process is reinforced and which can be manufactured with excellent yield. Therefore, the electronic apparatus having high cost performance can be provided.

It is to be noted that the embodiment is not limited to the above embodiment and can be executed in the following form.

### First Variation

As described above, the short-circuit wiring 66 may connect wirings (Vddx, Vddy) to each other to which a second predetermined potential (approximately 15V) which is different from a predetermined potential is supplied among power supply wirings instead of connecting to the GND as one of power supply wirings of the data line driving circuit 22 and the scan line driving circuits 24. To be more specific, the wiring (Vddx, third constant potential wiring) of the data line driving circuit 22 and the wiring (Vddy, fourth constant potential wiring) of the scan line driving circuits 24 are electrically connected to each other through the respective external connection terminals 23 (third terminal, fourth terminal).

A third static electricity protection circuit is electrically connected to the third constant potential wiring which connects the third terminal and the data line driving circuit 22. A fourth static electricity protection circuit is electrically connected to the fourth constant potential wiring which connects the fourth terminal and the scan line driving circuits 24. The third terminal and the fourth terminal at the same predetermined potential are electrically connected to each other with the second short-circuit wiring. With this, since power supply wirings at the same potential are connected to each other, the potential can be fixed. Therefore, the static electricity can be dispersed with the wirings at the same potential. Accordingly, charges can be prevented from being concentrated on a part of the wirings so that the transistors and the like can be prevented from being broken due to static electricity.

### Second Variation

As described above, targets to be protected from the static electricity are not limited to the TFT elements (transistors) included in the data line driving circuit 22 and the scan line driving circuits 24 and include semiconductor elements, diodes, and the like provided in the driving circuits.

What is claimed is:

1. An electrooptic device substrate on which a plurality of electrooptic devices are formed, wherein a first electrooptic device of the plurality of electrooptic devices includes:
a first terminal;
a second terminal; and
a short-circuit wiring which is electrically connected to the first terminal and the second terminal, the short-circuit wiring including a first portion that extends from the first terminal toward a second electrooptic device of the plurality of electrooptic devices which is adjacent to the first electrooptic device, a second portion that extends from the second terminal toward the second electrooptic device, and a third portion positioned in the second electrooptic device that connects between the first portion and the second portion.

2. The electrooptic device substrate according to claim 1, wherein the first electrooptic device includes:
a first circuit;
a second circuit;
a first wiring electrically connected to the first terminal and the first circuit;
a second wiring electrically connected to the second terminal and the second circuit;
a first static electricity protection circuit electrically connected to the first wiring; and
a second static electricity protection circuit electrically connected to the second wiring.

3. The electrooptic device substrate according to claim 1,
the first electrooptic device having a plurality of wiring layers, and
the short-circuit wiring being connected to a wiring layer from the plurality of wiring layers which, in a cross-sectional view, and being closest to the substrate among the plurality of wiring layers.

4. The electrooptic device substrate according to claim 1, wherein the first electrooptic device includes:
a third terminal;
a fourth terminal; and
a second short-circuit wiring electrically connected to the third terminal and the fourth terminal, the second short-circuit wiring including a fourth portion that extends from the third terminal toward the second electrooptic device, a fifth portion that extends from the fourth terminal toward the second electrooptic device, and a sixth portion positioned in the second electrooptic device that connects between the third portion and the fourth portion.

5. The electrooptic device substrate according to claim 4, wherein the first electrooptic device includes:
a third wiring electrically connected to the third terminal and the first circuit;
a fourth wiring electrically connected to the fourth terminal and the second circuit;
a third static electricity protection circuit electrically connected to the third wiring; and
a fourth static electricity protection circuit electrically connected to the fourth wiring.

6. The electrooptic device substrate according to claim 1, wherein the short-circuit wiring is formed at a same layer as a scan line for the first electrooptic device.

7. The electrooptic device substrate according to claim 1, wherein the short-circuit wiring is formed on a wiring layer closest to the substrate.

8. The electrooptic device substrate according to claim 1, wherein the short-circuit wiring is selected from a group of low-resistance wiring consisting of aluminum and polysilicon.

9. An electrooptic device formed by using the electrooptic device substrate according to claim 1.

10. An electronic apparatus including the electrooptic device according to claim 9.

11. A method of manufacturing an electrooptic device, comprising:
forming a first circuit;
forming a second circuit;
forming a first terminal;
forming a second terminal;
forming a first wiring electrically connected to the first terminal and the first circuit;
forming a second wiring electrically connected to the second terminal and the second circuit;
forming a short-circuit wiring electrically connected to the first terminal and the second terminal, the short-circuit wiring including a first portion that extends from the first terminal toward a second electrooptic device of the plurality of electrooptic devices which is adjacent to the first electrooptic device, a second portion that extends from the second terminal toward the second electrooptic device, and a third portion positioned in the second electrooptic device that connects between the first portion and the second portion; and
cutting the short-circuit wiring.

12. The method according to claim 11, further comprising:
forming a first static electricity protection circuit electrically connected to the first wiring;
forming a second static electricity protection circuit electrically connected to the second wiring;

13. The method according to claim 11, wherein the short-circuit wiring is formed at a same layer as a scan line for the electrooptic device.

14. The method according to claim 11, wherein the electrooptic device is formed on a substrate and the short-circuit wiring is formed on a wiring layer closest to the substrate.

15. The method according to claim 11, wherein the forming the short-circuit wiring is performed prior to forming switching elements in the first circuit and the second circuit.

16. The method according to claim 11, wherein the electrooptic device is formed on a mother substrate comprising a plurality of electrooptic devices, and the cutting the short-circuit wiring is performed when dividing the mother substrate into the plurality of electroptic devices.

17. The method according to claim 11, further comprising:
forming a third terminal;
forming a fourth terminal;
forming a third wiring electrically connected to the third terminal and the first terminal;
forming a fourth wiring electrically connected to the fourth terminal and the second terminal;
forming a third static electricity protection circuit electrically connected to the third wiring;
forming a fourth static electricity protection circuit electrically connected to the fourth wiring; and
forming a second short-circuit wiring electrically connected to the third terminal and the fourth terminal, the second short-circuit wiring including a fourth portion that extends from the third terminal toward the second electrooptic device, a fifth portion that extends from the fourth terminal toward the second electrooptic device, and a sixth portion positioned in the second electrooptic device that connects between the third portion and the fourth portion; and
cutting the second short-circuit wiring.

18. An electrooptic device substrate on which a plurality of electrooptic devices are formed, wherein a first electrooptic device of the plurality of electrooptic devices includes:
a first circuit;
a second circuit;
a first terminal;
a second terminal;
a first wiring electrically connected to the first terminal and the first circuit;
a second wiring electrically connected to the second terminal and the second circuit;
a first static electricity protection circuit electrically connected to the first wiring;
a second static electricity protection circuit electrically connected to the second wiring; and
a short-circuit wiring electrically connected to the first terminal and the second terminal at an outer side with respect to a scribe line that is in between the first electrooptic device and a second electrooptic device of the plurality of electrooptic devices which is adjacent to the first electrooptic device.
